(19) United States
(12) Patent Application Publication
(10) Pub. No.: US 2008/0088365 A1
(43) Pub. Date: Apr. 17, 2008

(54) Semiconductor device and method for decreasing noise of output driver

(75) Inventor: Young-Chan Jang, Yongin-si (KR)

Correspondence Address: MILLS & ONELLO LLP, ELEVEN BEACON STREET, SUITE 605, BOSTON, MA, 02108, US

(73) Assignee: Samsung Electronics Co., Ltd., Suwon-si (KR)

(21) Appl. No.: 11/820,611

(22) Filed: Jun. 20, 2007

(30) Foreign Application Priority Data
Oct. 16, 2006 (KR) 10-2006-0100538

(51) Int. Cl. G06G 7/12; H03K 3/00

(52) U.S. Cl. 327/563; 327/108

(57) ABSTRACT

In a semiconductor device and method for decreasing noise of an output driver block, the semiconductor device monitors differentially amplified voltages output from an output driver block and controls a voltage level at a cross-over point between the differentially amplified voltages so that noise that may be caused by reactance occurring in the output driver block can be removed and so that inter-symbol interference (ISI) that may be caused when a voltage level of a serialized input data is interfered with a voltage level of previously input data can be prevented.

### CROSS-REFERENCE TO RELATED PATENT APPLICATION

This application claims priority under 35 U.S.C. § 119 to Korean Patent Application No. 10-2006-0100538, filed on Oct. 16, 2006, the disclosure of which is hereby incorporated by reference herein as if set forth in its entirety.

### FIELD OF THE INVENTION

The present invention relates to a semiconductor device, and more particularly, to a semiconductor device and method for decreasing noise of an output driver.

### BACKGROUND OF THE INVENTION

Data in a memory core of a semiconductor memory device is commonly output through an output buffer. The output buffer serializes data, which is input in parallel based on a clock signal, before outputting the data.

FIG. 1 is a functional block diagram of a conventional semiconductor device 10. Referring to FIG. 1, the conventional semiconductor device 10 includes a data pipeline circuit 20, a first multiplexer (MUX) 40, a first buffer 50, a second MUX 60, a second buffer 70, and an output driver block 80.

The data pipeline circuit 20 aligns or delays data, which is output from a memory cell core block, and then transmits first data MUXIN to the first MUX 40 and second data MUXINB to the second MUX 60.

The first MUX 40 multiplexes the first data MUXIN, which is output from the data pipeline circuit 20, based on a clock signal CLK. The first buffer 50 buffers a signal MUX0 output from the first MUX 40 to pull the signal MUX0 up to a first power supply voltage or down to a second power supply voltage, thereby outputting a signal V1 as a result of the buffering.

The second MUX 60 multiplexes the second data MUXINB, which is output from the data pipeline circuit 20, based on the clock signal CLK. The second data MUXINB is a differential data signal that has a phase that is 180° different from that of the first data MUXIN. The second buffer 70 buffers a signal MUX0B output from the second MUX 60 to pull the signal MUX0B up to the first power supply voltage or down to the second power supply voltage, thereby outputting a signal V3 as a result of the buffering.

The output driver block 80 receives the signals V1 and V3 respectively from the first and second buffers 50 and 70 and differentially amplifies the signals V1 and V3, thereby outputting differentially amplified signals V9 and V11. Generally, the output driver block 80 includes a first differential amplifier 82 and a second differential amplifier 84, which are connected in cascade in order to increase current driving performance. Signals V5 and V7 generated through differential amplification of the first differential amplifier 82 are differentially amplified again by the second differential amplifier 84, so that noise is removed from the signals V5 and V7 and so that driving currents respectively flowing in data output terminals DQ and DQN are increased.

However, the signals V1 and V3 are respectively output from the first and second buffers 50 and 70 in full swing from the first power supply voltage to the second power supply voltage. Accordingly, a full-swing level is different from a voltage level that drives the first differential amplifier 82. The difference between the full-swing level and the driving voltage level changes the tail current of the first differential amplifier 82, and thus, noise can be generated due to the reactance of the first differential amplifier 82. FIG. 2 illustrates voltage waveforms of a drain node of a bias transistor included in the first differential amplifier 82 illustrated in FIG. 1. Referring to FIG. 2, the voltage waveforms of the drain node of the bias transistor included in the first differential amplifier 82 are irregular. In this case, it may be anticipated that noise of L*di/dt is induced by reactance.

Moreover, when a voltage level of data serialized by the first MUX 40 or the second MUX 60 is input to the output driver block 80, it may be interfered with by a voltage level of previously input data, that is, inter-symbol interference (ISI) may occur.

### SUMMARY OF THE INVENTION

Some embodiments of the present invention provide a semiconductor device and method for decreasing noise, which may occur due to reactance, and inter-symbol interference (ISI) in an output driver of the semiconductor device.

In a first aspect, there is provided a semiconductor device including an output circuit unit configured to output a first signal and a second signal, which is an inverted signal of the first signal, based on data output from a memory cell core block; an output driver configured to differentially amplify the first signal and the second signal and to generate a third signal and a fourth signal; and a control signal generation unit configured to generate a k-bit control signal for controlling a voltage level at a cross-over point between the first signal and the second signal based on a reference signal and at least one of the third and fourth signals, where “k” is a positive integer.

The control signal generation unit may compare a voltage level of at least one of the third and fourth signals with the reference signal and generate the k-bit control signal for controlling a driving strength of a PMOS transistor or an NMOS transistor included in the output circuit unit based on a result of the comparison.

The output circuit unit may include a first multiplexer configured to multiplex the data output from the memory cell core block based on a clock signal; a first signal level adjustor configured to drive a signal output from the first multiplexer to a level of a first power supply voltage or a level of a second power supply voltage in response to the k-bit control signal so as to output the first signal; a second multiplexer configured to multiplex inverted data of the data output from the memory cell core block based on the clock signal; and a second signal level adjustor configured to drive a signal output from the second multiplexer to the level of the first power supply voltage or the level of the second power supply voltage in response to the k-bit control signal so as to output the second signal.

The first signal level adjustor may include a first switch unit configured to transmit the signal output from the first multiplexer in response to a first switching control signal; a first pull-up section configured to pull an output node of the first signal level adjustor up to the level of the first power supply voltage in response to a signal output from the first switch unit and the k-bit control signal; a second switch unit configured to transmit the signal output from the first multiplexer in response to a second switching control signal; and a first pull-down section configured to pull the output node of the first signal level adjustor down to the level of the second power supply voltage based on a signal output from the second switch. The second signal level adjustor may include a third switch unit configured to transmit the signal output from the second multiplexer in response to a third switching control signal; a second pull-up section configured to pull an output node of the second signal level adjustor up to the level of the first power supply voltage in response to a signal output from the third switch unit and the k-bit control signal; a fourth switch unit configured to transmit the signal output from the second multiplexer in response to a fourth switching control signal; and a second pull-down section configured to pull the output node of the second signal level adjustor down to the level of the second power supply voltage based on a signal output from the fourth switch.

The first signal level adjustor may alternatively include a first switch unit configured to transmit the signal output from the first multiplexer in response to a first switching control signal; a first pull-up section configured to pull an output node of the first signal level adjustor up to the level of the first power supply voltage in response to a signal output from the first switch; a second switch unit configured to transmit the signal output from the first multiplexer in response to a second switching control signal; and a first pull-down section configured to pull the output node of the first signal level adjustor down to the level of the second power supply voltage based on a signal output from the second switch unit and the k-bit control signal. The second signal level adjustor may include a third switch unit configured to transmit the signal output from the second multiplexer in response to a third switching control signal; a second pull-up section configured to pull an output node of the second signal level adjustor up to the level of the first power supply voltage in response to a signal output from the third switch; a fourth switch unit configured to transmit the signal output from the second multiplexer in response to a fourth switching control signal; and a second pull-down section configured to pull the output node of the second signal level adjustor down to the level of the second power supply voltage based on a signal output from the fourth switch unit and the k-bit control signal.

The first signal level adjustor may alternatively include a first pull-up section configured to pull an output node of the first signal level adjustor up to the level of the first power supply voltage in response to the signal output from the first multiplexer and a first pull-down section configured to pull the output node of the first signal level adjustor down to the level of the second power supply voltage based on the signal output from the first multiplexer and the k-bit control signal. The second signal level adjustor may include a second pull-up section configured to pull an output node of the second signal level adjustor up to the level of the first power supply voltage in response to the signal output from the second multiplexer and a second pull-down section configured to pull the output node of the second signal level adjustor down to the level of the second power supply voltage based on the signal output from the second multiplexer and the k-bit control signal.

The output driver block may include a first differential amplifier configured to receive the first signal and the second signal and to differentially amplify the first signal and the second signal, and a second differential amplifier configured to receive signals output from the first differential amplifier and to differentially amplify the signals so as to output the third signal and the fourth signal.

The control signal generation unit may further include a comparator configured to compare a voltage level at a cross-over point between the signals output from the first differential amplifier with the reference signal and to generate a comparison signal corresponding to a result of the comparison, and a controller configured to generate the k-bit control signal for controlling the voltage level at the cross-over point based on the comparison signal.

The control signal generation unit may alternatively include a first integrator configured to integrate a difference between a first output signal of the first differential amplifier and the reference signal and to generate a first integration signal; a second integrator configured to integrate a difference between a second output signal of the first differential amplifier and the reference signal and to generate a second integration signal; a comparator configured to compare the first integration signal with the second integration signal and to generate a comparison signal corresponding to a result of the comparison; and a controller configured to generate the k-bit control signal based on the comparison signal.

The control signal generation unit may alternatively include a comparator configured to compare one of the third and fourth signals with the reference signal and to generate a comparison signal corresponding to a result of the comparison; and a controller configured to generate the k-bit control signal based on the comparison signal.

Alternatively, the control signal generation unit may include a first integrator configured to integrate a difference between the third signal and the reference signal and to generate a first integration signal; a second integrator configured to integrate a difference between the fourth signal and the reference signal and to generate a second integration signal; a comparator configured to compare the first integration signal with the second integration signal and to generate a comparison signal corresponding to a result of the comparison; and a controller configured to generate the k-bit control signal based on the comparison signal.

In another aspect, there is provided a data output method including outputting a first signal and a second signal, which is an inverted signal of the first signal, based on data output from a memory cell core block; generating a third signal and a fourth signal by differentially amplifying the first signal and the second signal; and generating a k-bit control signal for controlling a voltage level at a cross-over point between the first signal and the second signal based on a reference signal and at least one of the third and fourth signals, where “k” is a positive integer.

The generating of the k-bit control signal may include comparing one of the third and fourth signals with the reference signal and generating a comparison signal corresponding to a result of the comparison; and generating the k-bit control signal based on the comparison signal.

The generating of the k-bit control signal may include integrating a difference between the third signal and the reference signal and generating a first integration signal; integrating a difference between the fourth signal and the reference signal and generating a second integration signal; comparing the first integration signal with the second integration signal and generating a comparison signal corresponding to a result of the comparison; and generating the k-bit control signal for controlling a driving strength of the first signal and the second signal based on the comparison signal.

### BRIEF DESCRIPTION OF THE DRAWINGS

The above and other features and advantages of the embodiments of the present invention will become more apparent by describing in detail exemplary embodiments thereof with reference to the attached drawings in which:

FIG. 1 is a functional block diagram of a conventional semiconductor device;

FIG. 2 illustrates voltage waveforms of a drain node of a bias transistor included in an output driver block illustrated in FIG. 1;

FIG. 3 is a block diagram of a semiconductor device according to some embodiments of the present invention;

FIGS. 4A and 4B are circuit diagrams of a signal level adjustor included in an output circuit unit illustrated in FIG. 3, according to some embodiments of the present invention;

FIG. 5 is a circuit diagram of an output driver block illustrated in FIG. 3, according to some embodiments of the present invention;

FIG. 6 is a graph illustrating a drain-source voltage of a bias transistor included in the output driver block illustrated in FIG. 3;

FIG. 7 is a graph illustrating waveforms of signals output from the signal level adjustor included in the output circuit unit illustrated in FIG. 3;

FIG. 8 is a block diagram of a semiconductor device according to other embodiments of the present invention;

FIG. 9 is a graph illustrating waveforms of signals output from an output driver block included in the semiconductor device illustrated in FIG. 8;

FIG. 10A is an eye diagram illustrating output voltages of the conventional semiconductor device illustrated in FIG. 1; and

FIG. 10B is an eye diagram illustrating output voltages of the semiconductor device illustrated in FIG. 3.

### DETAILED DESCRIPTION OF EMBODIMENTS OF THE INVENTION

Embodiments of present invention now will be described more fully hereinafter with reference to the accompanying drawings. The invention may, however, be embodied in many different forms and should not be construed as limited to the embodiments set forth herein. Rather, these embodiments are provided so that this disclosure will be thorough and complete. In the drawings, like numbers refer to like elements throughout.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein, the term “and/or” includes any and all combinations of one or more of the associated listed items and may be abbreviated as “/”.

It will be understood that, although the terms first, second, etc. may be used herein to describe various elements, these elements should not be limited by these terms. These terms are only used to distinguish one element from another. For example, a first signal could be termed a second signal, and, similarly, a second signal could be termed a first signal without departing from the teachings of the disclosure.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and/or the present application, and will not be interpreted in an idealized or overly formal sense unless expressly so defined herein.

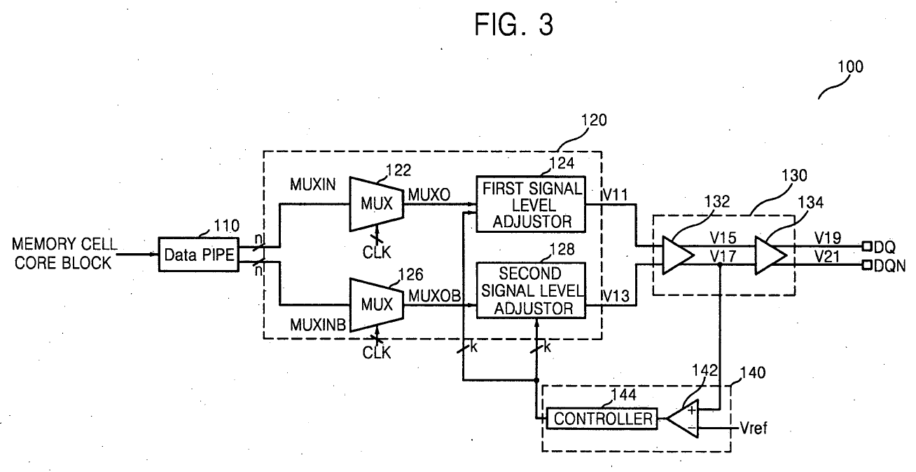

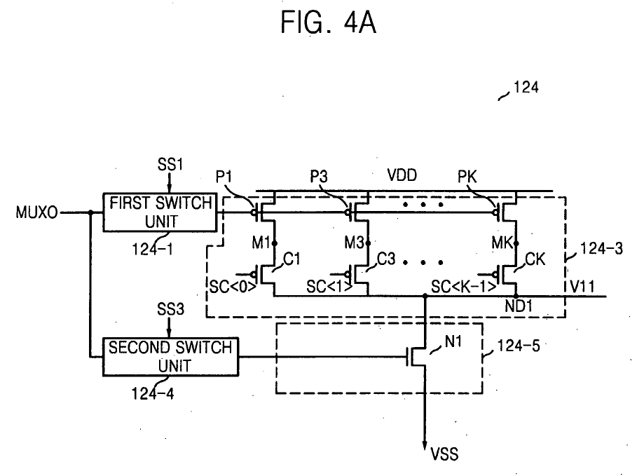

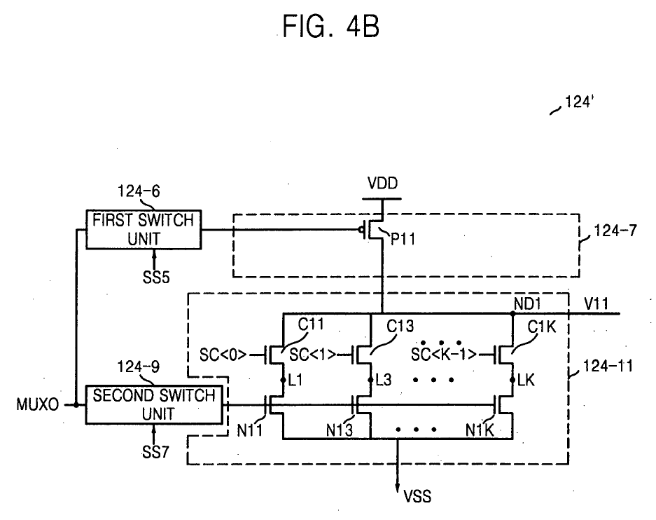

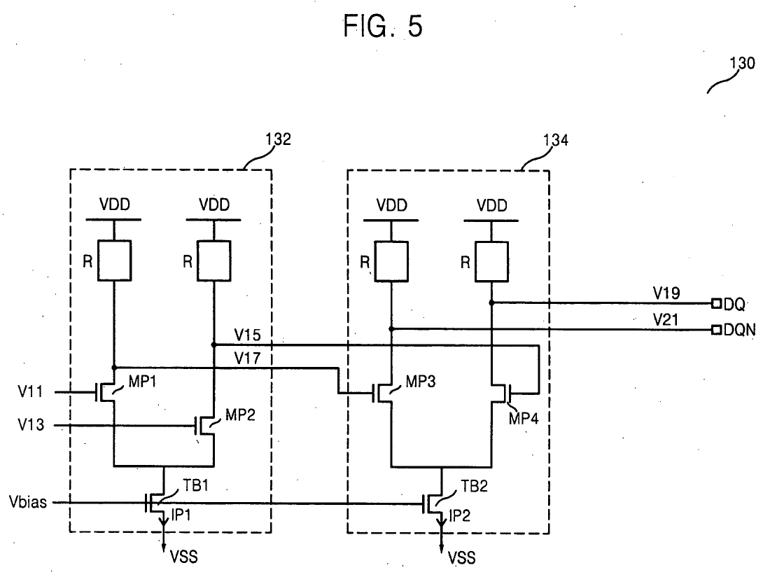

FIG. 3 is a block diagram of a semiconductor device according to some embodiments of the present invention. FIGS. 4A and 4B are circuit diagrams of a signal level adjustor included in an output circuit unit illustrated in FIG. 3 and FIG. 5 is a circuit diagram of an output driver block illustrated in FIG. 3.

Referring to FIG. 3 through 5, a semiconductor device 100 according to some embodiments of the present invention includes a data pipeline circuit 110, an output circuit unit 120, an output driver block 130, and a first control signal generation unit 140. The data pipeline circuit 110 aligns or delays data output from a data circuit, for example memory cell core block, and then transmits first data MUXIN and second data MUXINB_to the output circuit unit 120. The output circuit unit 120 outputs a first signal V11 and a second signal V13, which is an inverted signal of the first signal V11, based on the data output from the data pipeline circuit 110.

The output circuit unit 120 includes a first multiplexer (MUX) 122, a first signal level adjustor 124, a second MUX 126, and a second signal level adjustor 128. The first MUX 122 multiplexes the first data MUXIN based on a clock signal CLK, thereby converting n-bit data, i.e., the first data MUXIN, which is input in parallel, into serial data synchronized with the clock signal CLK. The first signal level adjustor 124 drives a signal MUX0 output from the first MUX 122 to a level of a first power supply voltage VDD or a level of a second power supply voltage VSS in response to a k-bit control signal output from the first control signal generation unit 140.

In a first embodiment illustrated in FIG. 4A, the first signal level adjustor 124 includes a first switch unit 124-1, a pull-up section 124-3, a second switch unit 1244, and a pull-down section 124-5. The first switch unit 124-1 transmits the signal MUX0 output from the first MUX 122 to the pull-up section 124-3 in response to a first switching control signal SS1. The first switching control signal SS1 is generated by an external test device (not shown) or an external controller (not shown) and turns on or off the first switch unit 124-1 in order to determine a voltage at a cross-over point between the first signal V11 and the second signal V13. The pull-up section 124-3 pulls an output node ND1 of the first signal level adjustor 124 up to the level of the first power supply voltage VDD in response to a signal output from the first switch unit 124-1 and the control signal of “k” bits SC<0> through SC<k−1>.

The pull-up section 124-3 includes a group of first PMOS transistors P1, P3, . . . , Pk and a group of second PMOS transistors C1, C3, . . . , Ck. The first PMOS transistors P1, P3, . . . , Pk respectively pull first nodes M1, M3, . . . , Mk up to the level of the first power supply voltage VDD based on the signal output from the first switch unit 124-1. The second PMOS transistors C1, C3, . . . , Ck pull the output node ND1 of the first signal level adjustor 124 to voltages of the first nodes M1, M3, . . . , Mk, respectively in response to the “k” bits SC<0> through SC<k−1>, respectively, of the control signal. The second switch unit 124-4 transmits the signal MUX0 output from the first MUX 122 to the pull-down section 124-5 in response to a second switching control signal SS3. The second switching control signal SS3 is generated by an external test device (not shown) or an external controller (not shown) and turns on or off the second switch unit 124-4 in order to check a voltage at the cross-over point between the first signal V11 and the second signal V13. The pull-down section 124-5 includes an NMOS transistor N1 connected between the output node ND1 and the second power supply voltage VSS and pulls the output node ND1 of the first signal level adjustor 124 down to the level of the second power supply voltage VSS based on a signal output from the second switch unit 124-4. Alternatively, the pull-down section 124-5 may include a plurality of NMOS transistors.

According to some embodiments of the present invention, in order to sense a voltage at the cross-over point between the first and second signals V11 and V13, the first and second signal level adjustors 124 and 128 may operate as follows.

In a transmission mode for transmitting data from the data pipeline circuit 110, the first switch unit 124-1 transmits the signal MUX0 output from the first MUX 122 to the first PMOS transistors P1, P3, . . . , Pk. In a test mode for detecting the cross-over point, the first switch unit 124-1 outputs a switching signal for turning on the first PMOS transistors P1, P3, . . . , Pk. For instance, the first switch unit 124-1 outputs a switching signal at a second logic state (e.g., a low level) based on the first switching control signal SS1 at a first logic state (e.g., a high level) so as to turn on the first PMOS transistors P1, P3, . . . , Pk.

The second switch unit 124-4 transmits the signal MUX0 output from the first MUX 122 to the NMOS transistor N1 in the transmission mode and outputs a switching signal for turning on the NMOS transistor N1 in the test mode. For instance, the second switch unit 124-4 outputs a switching signal at the first logic state (e.g., the high level) based on the second switching control signal SS3 at the second logic state (e.g., the low level) so as to turn on the NMOS transistor N1.

In other words, in the test mode, the first PMOS transistors P1, P3, . . . , Pk and the NMOS transistor N1 in the first signal level adjustor 124 and first PMOS transistors (not shown) and an NMOS transistor (not shown) in the second signal level adjustor 128 are all turned on so that a voltage may be induced at the cross-over point between the first and second signals V11 and V13.

In a second embodiment, illustrated at FIG. 4B, a first signal level adjustor 124′ may include a first switch unit 124-6, a pull-up section 124-7, a second switch unit 124-9, and a pull-down section 124-11, as illustrated in FIG. 4B.

The first switch unit 124-6 transmits the signal MUX0 output from the first MUX 122 to the pull-up section 124-7 in response to a first switching control signal SS5. The first switching control signal SS5 is generated by an external test device (not shown) or an external controller (not shown) and turns on or off the first switch unit 124-6 in order to check a voltage at the cross-over point between the first signal V11 and the second signal V13. The pull-up section 124-7 includes a PMOS transistor P11 connected between the first power supply voltage VDD and the output node ND1 of the first signal level adjustor 124′ and pulls the output node ND1 up to the level of the first power supply voltage VDD in response to a signal output from the first switch unit 124-6. Alternatively, the pull-up section 124-7 may include a plurality of PMOS transistors.

The second switch unit 124-9 transmits the signal MUX0 output from the first MUX 122 to the pull-down section 124-11 in response to a second switching control signal SS7. The second switching control signal SS7 is generated by an external test device (not shown) or an external controller (not shown) and turns on or off the second switch unit 124-9 in order to check a voltage at the cross-over point between the first signal V11 and the second signal V13. The pull-down section 124-11 pulls the output node ND1 of the first signal level adjustor 124′ down to the level of the second power supply voltage VSS based on a signal output from the second switch unit 124-9 and the “k” bits SC<0> through SC<k−1> of the control signal.

The pull-down section 124-11 includes a group of first NMOS transistors N11, N13, . . . , N1k_ and a group of second NMOS transistors C11, C13, . . . , C1k. The first NMOS transistors N11, N13, . . . , N1k respectively pull first nodes L1, L3, . . . , Lk down to the level of the second power supply voltage VSS. The second NMOS transistors C1, C13, . . . , C1k respectively response to the “k” bits SC<0> through SC<k−1> of the control signal and decrease the output node ND1 of the first signal level adjustor 124′ to voltages of the first nodes L1, L3, . . . , Lk, respectively.

According to some embodiments of the present invention, in order to sense a voltage at the cross-over point between the first and second signals V11 and V13, the first and second signal level adjustors 124′ and 128 may operate as follows.

In a transmission mode for transmitting data from the data pipeline circuit 110, the first switch unit 124-6 transmits the signal MUX0 output from the first MUX 122 to the PMOS transistor P11. In a test mode for detecting the cross-over point, the first switch unit 124-6 outputs a switching signal for turning on the PMOS transistor P11. For instance, the first switch unit 124-6 outputs a switching signal at a second logic state (e.g., a low level) based on the first switching control signal SS5 at a first logic state (e.g., a high level) so as to turn on the PMOS transistor P11.

The second switch unit 124-9 transmits the signal MUX0 output from the first MUX 122 to the first NMOS transistor N11, N13, . . . , N1k in the transmission mode and outputs a switching signal for turning on the first NMOS transistor N11, N13, . . . , N1k in the test mode. For instance, the second switch unit 124-9 outputs a switching signal at the first logic state (e.g., the high level) based on the second switching control signal SS7 at the second logic state (e.g., the low level) so as to turn on the first NMOS transistor N11, N13, . . . , N1k.

In other words, in the test mode, the PMOS transistor P11 and the first NMOS transistor N11, N13, . . . , N1k in the first signal level adjustor 124′ and a PMOS transistor (now shown) and first NMOS transistors (not shown) in the second signal level adjustor 128 are all turned on so that a voltage may be induced at the cross-over point between the first and second signals V11 and V13.

According to some embodiments of the present invention, the pull-down section 124-5 illustrated in FIG. 4A may be replaced by the pull-down section 124-11 illustrated in FIG. 4B and the pull-up section 124-7 illustrated in FIG. 4B may be replaced by the pull-up section 124-3 illustrated in FIG. 4A.

Returning to FIG. 3, the second MUX 126 multiplexes the second data MUXINB based on the clock signal CLK, thereby converting n-bit data, i.e., the second data MUXINB, which is input in parallel, into serial data synchronized with the clock signal CLK. The second data MUXINB is a differential data signal that has a phase which is 180° different from that of the first data MUXIN.

The second signal level adjustor 128 drives a signal MUX0B output from the second MUX 126 to the level of the first power supply voltage VDD or the level of the second power supply voltage VSS in response to the k-bit control signal. The signal MUX0 output from the first MUX 122 and the signal MUX0B output from the second MUX 126 have a phase difference of about 180 degrees.

The structure and the operation of the second signal level adjustor 128 are similar to or the same as those of the first signal level adjustor 124, and thus detailed descriptions thereof will be omitted.

With reference to FIG. 5, the output driver block 130 differentially amplifies the first and second signals V11 and V13 and generates a third signal V19 and a fourth signal V21. The output driver block 130 includes a first differential amplifier 132 and a second differential amplifier 134.

The first differential amplifier 132 receives the first and second signals V11 and V13 and differentially amplifies the first and second signals V11 and V13. The first differential amplifier 132 includes a pair of transistors MP1 and MP2 which respectively response to the first signal V11 and the second signal V13, a load resistor R, and a bias transistor TB1 which operates in response to a bias voltage Vbias.

The second differential amplifier 134 receives signals V15 and V17 output from the first differential amplifier 132 and differentially amplifies the signals V15 and V17 so as to output the third and fourth signals V19 and V21. The second differential amplifier 134 includes a pair of transistors MP3 and MP4 which respectively response to the signals V15 and V17 output from the first differential amplifier 132, a load resistor R, and a bias transistor TB2 which operates in response to the bias voltage Vbias.

Returning to FIG. 3, the first control signal generation unit 140 generates the k-bit control signal (where “k” is a positive integer) for controlling the level of the voltage at the cross-over point between the first and second signals V11 and V13 based on the signal V15 or V17 output from the first differential amplifier 132 and a predetermined reference voltage level Vref. Alternatively, the first control signal generation unit 140 may generate the k-bit control signal for controlling the voltage level at the cross-over point based on the signal V19 or V21 output from the second differential amplifier 134 and the predetermined reference voltage level Vref. Here, the cross-over point indicates a point where the two signals V11 and V13 meet each other, or have substantially the same voltage level, when they transition from one level to another level.

The k-bit control signal may control the driving strength of the pull-up section 124-3, and more specifically, of the second PMOS transistors C1, C3, . . . , Ck in the first signal level adjustor 124. As a result, the voltage level at the cross-over point between the first and second signals V11 and V13 can be controlled. For instance, when all of the “k” bits of the control signal are at a first logic level, i.e., a low level, the second PMOS transistors C1, C3, . . . , Ck are all turned on and the rising slopes of the first and second signals V11 and V13 output from the first signal level adjustor 124 increase, and therefore, the voltage level at the cross-over point also increases. To the contrary, when all of the “k” bits of the control signal are at a second logic level, i.e., a high level, the second PMOS transistors C1, C3, . . . , Ck are all turned off and the falling slopes of the first and second signals V11 and V13 output from the first signal level adjustor 124 increase, and therefore, the voltage level at the cross-over point decreases.

The first control signal generation unit 140 includes a comparator 142 and a controller 144. The comparator 142 compares the signal V15 or V17 output from the first differential amplifier 132 with the predetermined reference voltage level Vref and generates a comparison signal corresponding to a result of the comparison. The predetermined reference voltage level Vref may be a target voltage level at the cross-over point.

In detail, the comparator 142 may calculate an average voltage level or a DC voltage level with respect to a signal input through a positive terminal, i.e., the first or second output signal V15 or V17 of the first differential amplifier 132 and compare the calculated voltage level with the reference voltage level Vref so as to output the comparison signal. The average voltage level or the DC voltage level with respect to the first and second output signal V15 or V17 correspond to the voltage level at a cross-over point between the first and second output signals V15 and V17. Accordingly, the first or second output signal V15 or V17 may be processed by a separate average calculator (not shown) before being input to the comparator 142.

For instance, when the voltage level at the cross-over point is higher than the reference voltage level Vref, the comparator 142 may output the comparison signal at a second logic level (e.g., a high level) so that the controller 144 turns off the second PMOS transistors C1, C3, . . . , Ck, thereby decreasing the voltage level at the cross-over point. When the voltage level at the cross-over point is lower than the reference voltage level Vref, the comparator 142 may output the comparison signal at a first logic level (e.g., a low level) so that the controller 144 turns on the second PMOS transistors C1, C3, . . . , Ck, thereby increasing the voltage level at the cross-over point.

The controller 144 generates the k-bit control signal based on the comparison signal. The controller 144 may be implemented, for example, using a counter (not shown) and a register (not shown), which correspond to each of bits in the comparison signal_output from the comparator 142. Each counter may increase or decrease a corresponding register in response to a corresponding bit in the comparison signal. For instance, the counter may decrease a value of the corresponding register by one step in response to the corresponding bit at a first logic level (e.g., a low level) and may decrease the value of the register by one step in response to the corresponding bit at a second logic level (e.g., a high level). A value stored in each register may be a binary digital code comprised of a plurality of bits (e.g., “k” bits) and may be input as a digital control signal to the first signal level adjustor 124 and/or the second signal level adjustor 128.

For instance, the controller 144 may output the k-bit control signal at the first logic level (i.e., the low level) to turn on the second PMOS transistors C1, C3, . . . , Ck and to increase the driving strength of the second PMOS transistors C1, C3, . . . , Ck. In addition, the controller 144 may output the k-bit control signal at the second logic level (i.e., the high level) to turn off the second PMOS transistors C1, C3, . . . , Ck and to decrease the driving strength of the second PMOS transistors C1, C3, . . . , Ck.

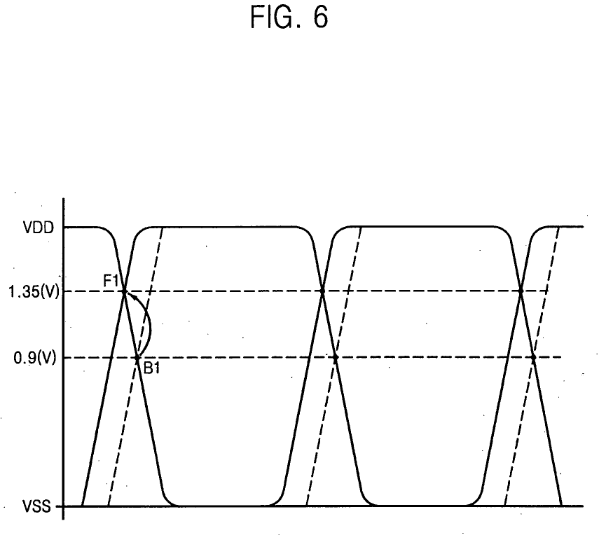

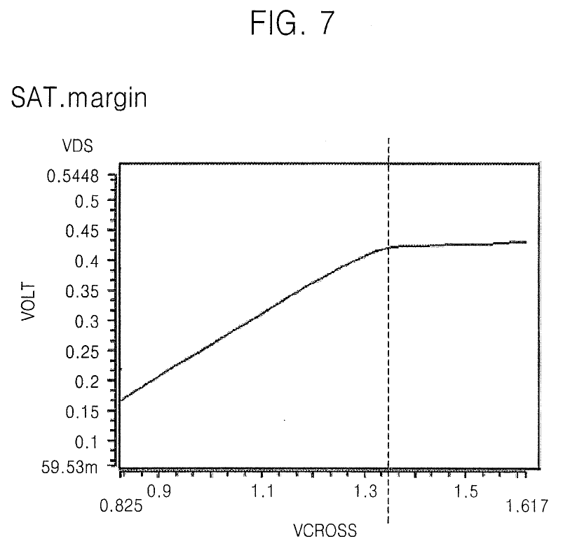

FIG. 6 is a graph illustrating a drain-source voltage of a bias transistor included in the output driver block 130 illustrated in FIG. 3. FIG. 7 is a graph illustrating waveforms of signals output from the first signal level adjustor 124 and the second level adjustor 128 included in the output circuit unit 120 illustrated in FIG. 3.

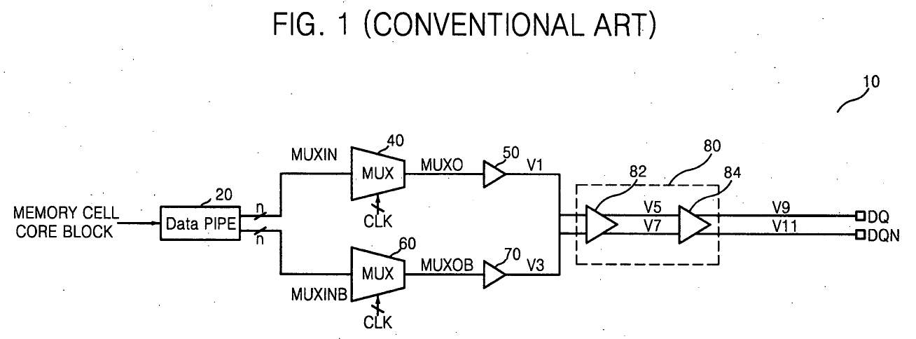

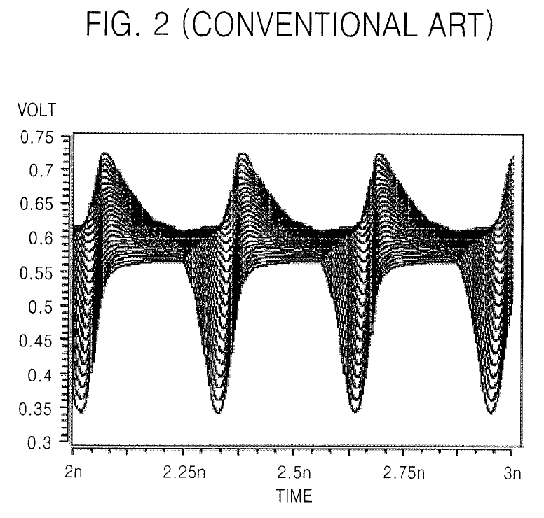

Referring to FIGS. 3 through 7, when the voltage level VCROSS at the cross-over point between the first and second signals V11 and V13 is about 1.35 V, a voltage VDS at a drain and a source of the bias transistor TB1 having a first tail current becomes constant, and therefore, current flowing in the bias transistor TB1 also becomes constant. Accordingly, as illustrated in FIG. 7, when the voltage level VCROSS at the cross-over point between the first and second signals V11 and V13 is increased from a point B1 to a point F1, the current flowing in the bias transistor TB1 becomes constant, and therefore, noise of L*di/dt caused by reactance of the first differential amplifier 82 (FIG. 1) can be removed.

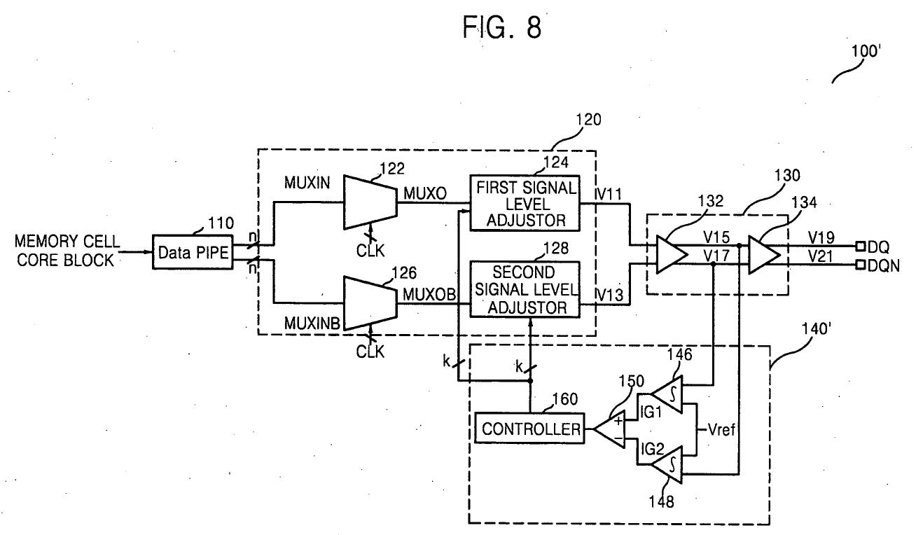

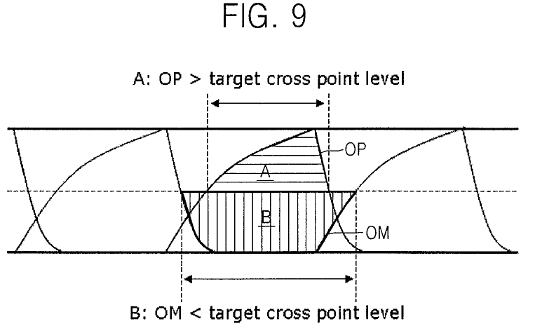

FIG. 8 is a block diagram of a semiconductor device 100′ according to other embodiments of the present invention. FIG. 9 is a graph illustrating waveforms of signals output from an output driver block included in the semiconductor device 100′ illustrated in FIG. 8. Referring to FIG. 4A and FIGS. 8 and 9, the semiconductor device 100′ has the same structure as the semiconductor device 100 illustrated in FIG. 3, with the exception that the semiconductor device 100′ includes a second control signal generation unit 140′ instead of the first control signal generation unit 140. The second control signal generation unit 140′ includes a first integrator 146, a second integrator 148, a comparator 150, and a controller 160.

The first integrator 146 integrates a difference between the first output signal V15 of the first differential amplifier 132 and a predetermined reference signal Vref and generates a first integration signal IG1. The second integrator 148 integrates a difference between the second output signal V17 of the first differential amplifier 132 and the reference signal Vref and generates a second integration signal IG2. The comparator 150 compares the first integration signal IG1 with the second integration signal IG2 and generates a comparison signal corresponding to a result of the comparison. The first data signal MUXIN and the second data signal MUXINB may be controlled to have predetermined values so that the first output signal V15 and the second output signal V17 are regularly toggled so as to control the voltage level at the cross-over point between the first and second signals V11 and V13.

For instance, referring to FIG. 9, the first integration signal IG1 corresponds to an area of a portion A and the second integration signal IG2 corresponds to an area of a portion B. Here, when the first integration signal IG1 is greater in area than the second integration signal IG2, the comparator 150 outputs the comparison signal at a second logic level (e.g., a high level) and the controller 160 turns off the second PMOS transistors C1, C3, . . . , Ck, thereby decreasing the voltage level at the cross-over point. To the contrary, when the first integration signal IG1 is smaller in area than the second integration signal IG2, the comparator 150 outputs the comparison signal at a first logic level (e.g., a low level) and the controller 160 turns on the second PMOS transistors C1, C3, . . . , Ck, thereby increasing the voltage level at the cross-over point.

The controller 160 generates the k-bit control signal based on the comparison signal. Like the controller 144 illustrated in FIG. 3, the controller 150 may be implemented by a counter (not shown) and a register (not shown), which correspond to each of bits in the comparison signal output from the comparator 150. The operation of the controller 160 is almost the same as that of the controller 144, and thus a detailed description thereof will be omitted.

The structure and the operation of the semiconductor device 100′ illustrated in FIG. 8 are almost the same as those of the semiconductor device 100 illustrated in FIG. 3, with the exception that the semiconductor device 100′ includes the second control signal generation unit 140′ instead of the first control signal generation unit 140. Thus, a detailed description thereof will be omitted.

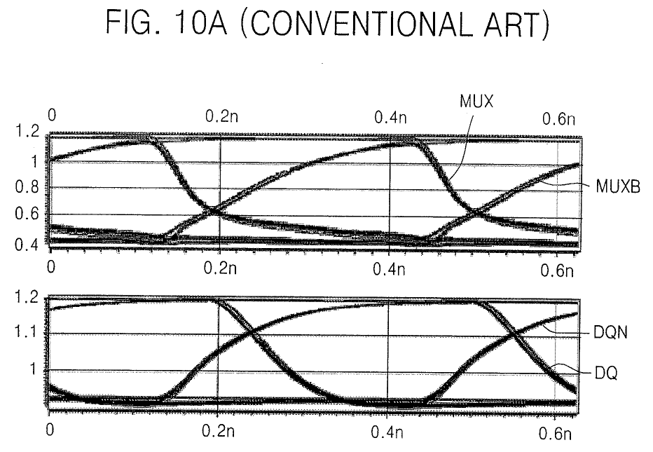

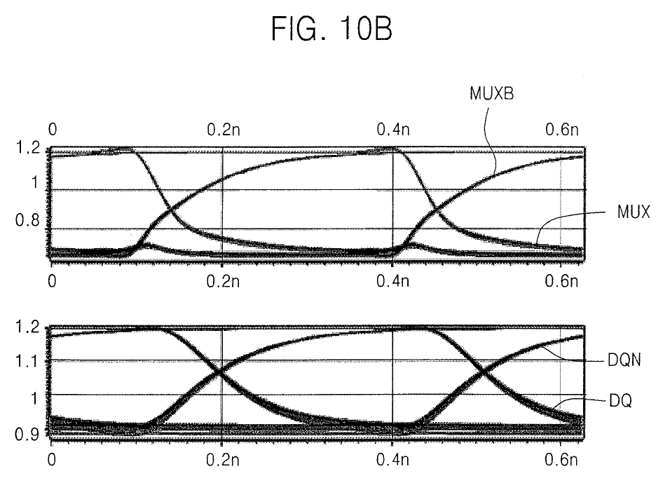

FIG. 10A is an eye diagram illustrating output voltages of the conventional semiconductor device 10 illustrated in FIG. 1. FIG. 10B is an eye diagram illustrating output voltages of the semiconductor device 100 illustrated in FIG. 3. Eyes illustrated in FIG. 10B are greater than those illustrated in FIG. 10A. Accordingly, it can be inferred that noise and inter-symbol interference (ISI) are removed from a signal in embodiments of the present invention.

As described above, according to some embodiments of the present invention, a voltage input to an output buffer of a semiconductor device is monitored and controlled so that noise that may be caused by reactance can be removed and so that ISI that may be caused when a voltage level of a serialized input data is interfered with a voltage level of previously input data can be prevented.

While embodiments of the present invention have been shown and described above, it will be understood by those of ordinary skill in the art that various changes in form and detail may be made herein without departing from the spirit and scope of the present invention, as defined by the following claims.

What is claimed is:

1. A semiconductor device comprising:
an output circuit unit configured to output a first signal and a second signal, which is an inverted signal of the first signal, based on data output from a memory cell core block;
an output driver block configured to differentially amplify the first signal and the second signal and to generate a third signal and a fourth signal; and
a control signal generation unit configured to generate a k-bit control signal for controlling a voltage level at a cross-over point between the first signal and the second signal based on a reference signal and at least one of the third and fourth signals, where “k” is a positive integer.

2. The semiconductor device of claim 1, wherein the control signal generation unit compares a voltage level of at least one of the third and fourth signals with the reference signal and generates the k-bit control signal for controlling a driving strength of a PMOS transistor or an NMOS transistor included in the output circuit unit based on a result of the comparison.

3. The semiconductor device of claim 1, wherein the output circuit unit comprises:
a first multiplexer configured to multiplex the data output from the memory cell core block based on a clock signal;
a first signal level adjustor configured to drive a signal output from the first multiplexer to a level of a first power supply voltage or a level of a second power supply voltage in response to the k-bit control signal so as to output the first signal;
a second multiplexer configured to multiplex inverted data of the data output from the memory cell core block based on the clock signal; and
a second signal level adjustor configured to drive a signal output from the second multiplexer to the level of the first power supply voltage or the level of the second power supply voltage in response to the k-bit control signal so as to output the second signal.

4. The semiconductor device of claim 3, wherein the first signal level adjustor comprises:
a first switch unit configured to transmit the signal output from the first multiplexer in response to a first switching control signal;
a first pull-up section configured to pull an output node of the first signal level adjustor up to the level of the first power supply voltage in response to a signal output from the first switch unit and the k-bit control signal;
a second switch unit configured to transmit the signal output from the first multiplexer in response to a second switching control signal; and
a first pull-down section configured to pull the output node of the first signal level adjustor down to the level of the second power supply voltage based on a signal output from the second switch, and
wherein the second signal level adjustor comprises:
a third switch unit configured to transmit the signal output from the second multiplexer in response to a third switching control signal;
a second pull-up section configured to pull an output node of the second signal level adjustor up to the level of the first power supply voltage in response to a signal output from the third switch unit and the k-bit control signal;
a fourth switch unit configured to transmit the signal output from the second multiplexer in response to a fourth switching control signal; and
a second pull-down section configured to pull the output node of the second signal level adjustor down to the level of the second power supply voltage based on a signal output from the fourth switch.

5. The semiconductor device of claim 4, wherein the first pull-up section comprises:
a group of first PMOS transistors configured to pull a corresponding group of first nodes up to the level of the first power supply voltage based on the signal output from the first multiplexer; and
a group of second PMOS transistors configured to raise the output node of the first signal level adjustor to a voltage of the corresponding group of the first nodes in response to the k-bit control signal, and
wherein the second pull-up section comprises:
a group of third PMOS transistors configured to pull a corresponding group of second nodes up to the level of the first power supply voltage based on the signal output from the second multiplexer; and
a group of fourth PMOS transistors configured to raise the output node of the second signal level adjustor to a voltage of the corresponding group of the second nodes in response to the k-bit control signal.

6. The semiconductor device of claim 3, wherein the first signal level adjustor comprises:
a first switch unit configured to transmit the signal output from the first multiplexer in response to a first switching control signal;
a first pull-up section configured to pull an output node of the first signal level adjustor up to the level of the first power supply voltage in response to a signal output from the first switch;
a second switch unit configured to transmit the signal output from the first multiplexer in response to a second switching control signal; and
a first pull-down section configured to pull the output node of the first signal level adjustor down to the level of the second power supply voltage based on a signal output from the second switch unit and the k-bit control signal, and
wherein the second signal level adjustor comprises:
a third switch unit configured to transmit the signal output from the second multiplexer in response to a third switching control signal;
a second pull-up section configured to pull an output node of the second signal level adjustor up to the level of the first power supply voltage in response to a signal output from the third switch;
a fourth switch unit configured to transmit the signal output from the second multiplexer in response to a fourth switching control signal; and
a second pull-down section configured to pull the output node of the second signal level adjustor down to the level of the second power supply voltage based on a signal output from the fourth switch unit and the k-bit control signal.

7. The semiconductor device of claim 6, wherein the first pull-down section comprises:
a group of first NMOS transistors configured to pull a corresponding group of first nodes down to the level of the second power supply voltage based on the signal output from the first multiplexer; and
a group of second NMOS transistors configured to decrease the output node of the first signal level adjustor to a voltage of the corresponding group of the first nodes in response to the k-bit control signal, and
wherein the second pull-down section comprises:
a group of third NMOS transistors configured to pull a corresponding group of second nodes down to the level of the second power supply voltage based on the signal output from the second multiplexer; and
a group of fourth NMOS transistors configured to decrease the output node of the second signal level adjustor to a voltage of the corresponding group of the second nodes in response to the k-bit control signal.

8. The semiconductor device of claim 1, wherein the output driver block comprises:
a first differential amplifier configured to receive the first signal and the second signal and to differentially amplify the first signal and the second signal; and
a second differential amplifier configured to receive signals output from the first differential amplifier and to differentially amplify the signals so as to output the third signal and the fourth signal.

9. The semiconductor device of claim 8, wherein the control signal generation unit comprises:
a comparator configured to compare a voltage level at a cross-over point between the signals output from the first differential amplifier with the reference signal and to generate a comparison signal corresponding to a result of the comparison; and
a controller configured to generate the k-bit control signal based on the comparison signal.

10. The semiconductor device of claim 8, wherein the control signal generation unit comprises:
a first integrator configured to integrate a difference between a first output signal of the first differential amplifier and the reference signal and to generate a first integration signal;
a second integrator configured to integrate a difference between a second output signal of the first differential amplifier and the reference signal and to generate a second integration signal;
a comparator configured to compare the first integration signal with the second integration signal and to generate a comparison signal corresponding to a result of the comparison; and
a controller configured to generate the k-bit control signal based on the comparison signal.

11. The semiconductor device of claim 1, wherein the control signal generation unit comprises:
a comparator configured to compare one of the third and fourth signals with the reference signal and to generate a comparison signal corresponding to a result of the comparison; and
a controller configured to generate the k-bit control signal based on the comparison signal.

12. The semiconductor device of claim 1, wherein the control signal generation unit comprises:
a first integrator configured to integrate a difference between the third signal and the reference signal and to generate a first integration signal;
a second integrator configured to integrate a difference between the fourth signal and the reference signal and to generate a second integration signal;
a comparator configured to compare the first integration signal with the second integration signal and to generate a comparison signal corresponding to a result of the comparison; and
a controller configured to generate the k-bit control signal based on the comparison signal.

13. A data output method comprising:
outputting a first signal and a second signal, which is an inverted signal of the first signal, based on data output from a memory cell core block;
generating a third signal and a fourth signal by differentially amplifying the first signal and the second signal; and
generating a k-bit control signal for controlling a voltage level at a cross-over point between the first signal and the second signal based on a reference signal and at least one of the third and fourth signals, where “k” is a positive integer.

14. The data output method of claim 13, wherein the generating of the k-bit control signal comprises:
comparing one of the third and fourth signals with the reference signal and generating a comparison signal corresponding to a result of the comparison; and
generating the k-bit control signal based on the comparison signal.

15. The data output method of claim 13, wherein the generating of the k-bit control signal comprises:
integrating a difference between the third signal and the reference signal and generating a first integration signal;
integrating a difference between the fourth signal and the reference signal and generating a second integration signal;
comparing the first integration signal with the second integration signal and generating a comparison signal corresponding to a result of the comparison; and
generating the k-bit control signal for controlling a driving strength of the first signal and the second signal based on the comparison signal.
